(19) United States
(12) Patent Application Publication
(10) Pub. No.: US 2024/0321618 A1
(43) Pub. Date: Sep. 26, 2024

(54) SEMICONDUCTOR MANUFACTURING APPARATUS AND SEMICONDUCTOR PACKAGE ALIGNMENT METHOD

(71) Applicant: SAMSUNG ELECTRONICS CO., LTD., SUWON-SI (KR)

(72) Inventors: Suhwan SHIM, Suwon-si (KR); Sungchul KIM, Suwon-si (KR); Sangho JANG, Suwon-si (KR); Youngshin CHOI, Suwon-si (KR)

(21) Appl. No.: 18/610,612

(22) Filed: Mar. 20, 2024

(30) Foreign Application Priority Data
Mar. 24, 2023 (KR) 10-2023-0039024
Apr. 18, 2023 (KR) 10-2023-0050941

(51) Int. Cl. H01L 21/68; H01L 21/66; H01L 21/67; H01L 21/673; H01L 21/683

(52) U.S. Cl. CPC H01L 21/681; H01L 21/67259; H01L 21/67333; H01L 21/6838; H01L 22/20

(57) ABSTRACT

A semiconductor manufacturing apparatus includes a semiconductor package. A tray has the semiconductor package seated thereon. An inspector inspects an alignment state of the semiconductor package. A protrusion is on a top surface of the tray and extends in a Z direction that is a vertical direction. The protrusion surrounds a side surface of the semiconductor package when the semiconductor package is in an aligned state. The semiconductor package overlaps at least a portion of the protrusion in the Z direction when the semiconductor package is in a misaligned state. An under vision camera detects a rotation angle of the semiconductor package with respect to an X-Y plane defined in a first horizontal direction X and a second horizontal direction Y that cross the Z direction. A picker moves the semiconductor package between the tray and an area above the under vision camera.

### CROSS-REFERENCE TO RELATED APPLICATIONS

This application claims priority under 35 U.S.C. § 119 to Korean Patent Application No. 10-2023-0039024, filed on Mar. 24, 2023 in the Korean Intellectual Property Office (KIPO) and Korean Patent Application No. 10-2023-0050941, filed on Apr. 18, 2023 in KIPO, the disclosures of which are incorporated by reference in their entireties herein.

### 1. TECHNICAL FIELD

The present disclosure relates to a semiconductor manufacturing apparatus and a semiconductor package alignment method, and more particularly, to a semiconductor manufacturing apparatus for aligning a semiconductor package to a target position and a semiconductor package alignment method.

### 2. DISCUSSION OF RELATED ART

Electronic components mounted on electronic products have become increasingly compact and light due to the recent demand for portable devices in the electronic products industry. To make electronic components compact and light, a semiconductor package mounted on the electronic components should be small in volume and capable of processing a large amount of data.

A semiconductor package is received in a tray and then transported to a subsequent manufacturing line. When the semiconductor package is seated on the tray in a misaligned state, a subsequent manufacturing process is delayed due to the misalignment of the semiconductor package to a target position.

### SUMMARY

The disclosure provides a semiconductor manufacturing apparatus and a semiconductor package alignment method for aligning a misaligned semiconductor package to a target position by using an inspector, an under vision camera, and a picker.

The disclosure is not necessarily limited to those mentioned above, and the disclosure that has not been mentioned will be clearly understood by one of skill in the art from the description below.

According to an embodiment of the present disclosure, a semiconductor manufacturing apparatus includes a semiconductor package. A tray has the semiconductor package seated thereon. An inspector inspects an alignment state of the semiconductor package. A protrusion is on a top surface of the tray and extends in a Z direction that is a vertical direction. The protrusion surrounds a side surface of the semiconductor package when the semiconductor package is in an aligned state. The semiconductor package overlaps at least a portion of the protrusion in the Z direction when the semiconductor package is in a misaligned state. An under vision camera detects a rotation angle of the semiconductor package with respect to an X-Y plane defined in a first horizontal direction X and a second horizontal direction Y that cross the Z direction. A picker moves the semiconductor package between the tray and an arca above the under vision camera.

According to an embodiment of the present disclosure, a semiconductor manufacturing apparatus includes a semiconductor package. A tray has the semiconductor package seated thereon. A vibrator is configured to vibrate the tray. An inspector inspects an alignment state of the semiconductor package. A protrusion is on a top surface of the tray and extends in a Z direction that is a vertical direction. The protrusion surrounds a side surface of the semiconductor package when the semiconductor package is in an aligned state. The semiconductor package overlaps at least a portion of the protrusion in the Z direction when the semiconductor package in a misaligned state. An under vision camera detects a rotation angle of the semiconductor package with respect to an X-Y plane defined in a first horizontal direction X and a second horizontal direction Y that cross the Z direction. A picker moves the semiconductor package between the tray and an area above the under vision camera. A controller controls movement of the semiconductor package that is in the misaligned state by the picker to correct a positional relationship between the semiconductor package and the tray based on a value detected by each of the inspector and the under vision camera. The picker includes a buffer directly contacting a top surface of the semiconductor package.

According to an embodiment of the present disclosure, a semiconductor package alignment method includes providing a tray having a plurality of semiconductor packages seated thereon. An alignment state of the plurality of semiconductor packages is inspected. A misaligned semiconductor package that is seated on the tray in a misaligned state is identified based on the inspection. The misaligned semiconductor package is separated from the tray by using a picker. The separated semiconductor package is moved to an area above an under vision camera. Correction values are calculated respectively for XY coordinates defined in a first horizontal direction X and a second horizontal direction Y and a rotation angle of the separated semiconductor package with respect to an X-Y plane defined in the first horizontal direction X and the second horizontal direction Y through the under vision camera. The separated semiconductor package is seated at a target position on the tray based on the calculated correction values. The tray includes a protrusion surrounding each of the plurality of semiconductor packages thereon. The misaligned semiconductor package overlaps the protrusion in a Z direction that is a vertical direction crossing the first horizontal direction X and second horizontal direction Y. The target position is a position where the semiconductor package does not overlap the protrusion in the Z direction.

### BRIEF DESCRIPTION OF THE DRAWINGS

Embodiments of the present disclosure will be more clearly understood from the following detailed description taken in conjunction with the accompanying drawings in which:

FIG. 1 is a schematic plan view of a semiconductor manufacturing apparatus according to an embodiment of the present disclosure;

FIGS. 2A to 2D are enlarged plan views of a region AA in FIG. 1 according to embodiments of the present disclosure;

FIG. 3 is a schematic flowchart of a semiconductor package alignment method according to an embodiment of the present disclosure;

FIGS. 4A to 4F are schematic cross-sectional views of a semiconductor manufacturing apparatus according to embodiments of the present disclosure;

FIG. 5 is a schematic plan view of a semiconductor package aligned by a semiconductor package alignment method according to an embodiment of the present disclosure;

FIG. 6 is a schematic flowchart of a semiconductor package alignment method according to an embodiment of the present disclosure;

FIG. 7 is a schematic plan view showing a semiconductor manufacturing apparatus according to an embodiment of the present disclosure; and

FIG. 8 is a schematic plan view showing a semiconductor manufacturing apparatus according to an embodiment of the present disclosure.

### DETAILED DESCRIPTION OF EMBODIMENTS

Hereinafter, embodiments will be described with reference to the attached drawings. In the drawings, like numerals denote like elements and redundant descriptions thereof will be omitted.

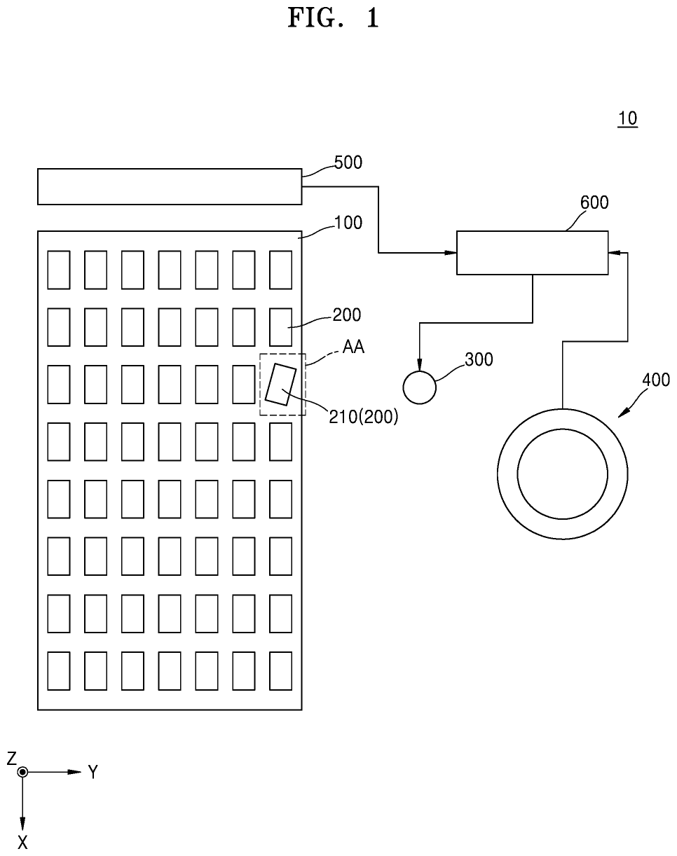

FIG. 1 is a schematic plan view of a semiconductor manufacturing apparatus according to an embodiment.

Referring to FIG. 1, in an embodiment a semiconductor manufacturing apparatus 10 may include a tray 100, a semiconductor package 200, an inspector 500, an under vision camera 400, and a picker 300. The tray 100 may include a plate on which the semiconductor package 200 is seated. According to an embodiment, the tray 100 may include, for example, a Jedec tray as a plate on which a plurality of semiconductor packages 200 are seated. However, embodiments of the present disclosure are not necessarily limited thereto. For example, the tray 100 may include any plate capable of receiving the semiconductor package 200.

According to an embodiment, the tray 100 may have a rectangular plate shape in a plan view (e.g., in a plane defined in the X-axis direction and Y-axis direction). In the drawings herein, the X-axis direction and the Y-axis direction may be parallel with the top surface of the tray 100 and perpendicular to each other. The Z-axis direction may perpendicular to the top or bottom surface of the tray 100. For example, the Z-axis direction may be perpendicular to an X-Y plane. However, embodiments of the present disclosure are not necessarily limited thereto and the X-axis, Y-axis and Z-axis directions may cross each other at various different angles.

In the drawings, a first horizontal direction, a second horizontal direction, and a vertical direction may be considered as follows. The first horizontal direction may be considered as the X-axis direction, the second horizontal direction may be considered as the Y-axis direction, and the vertical direction may be considered as the Z-axis direction.

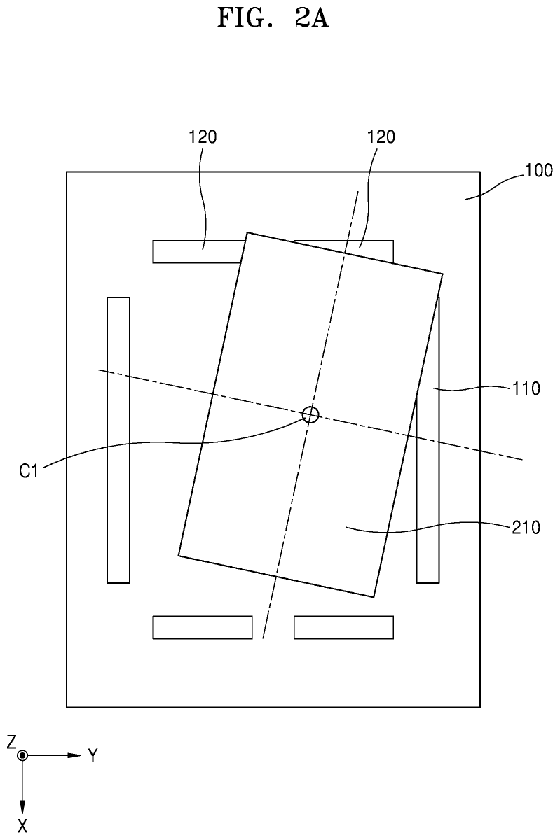

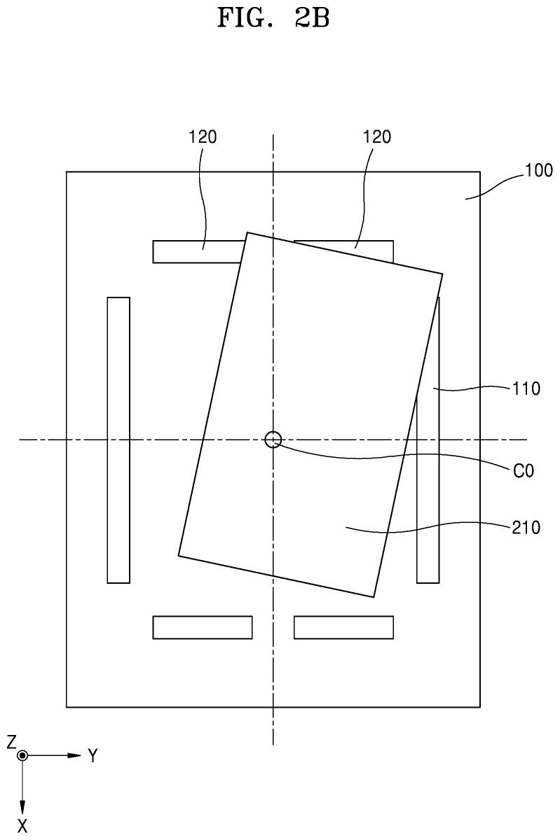

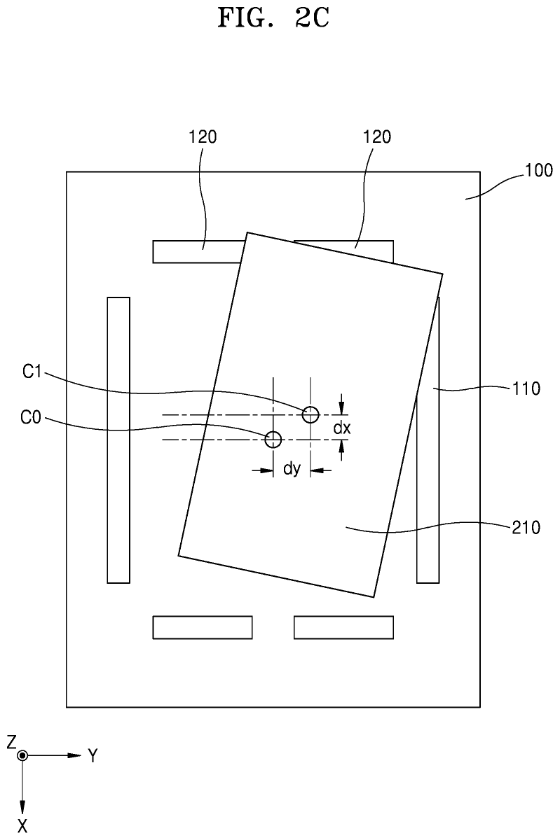

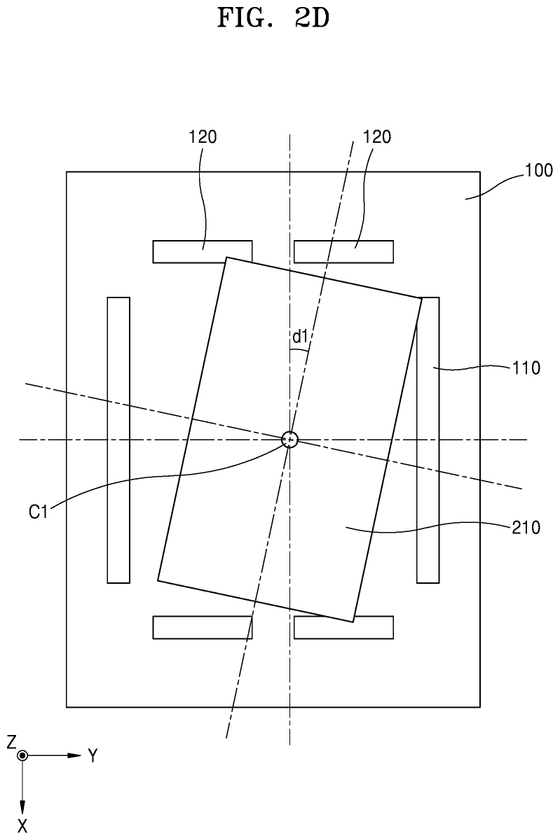

Protrusions 110 and 120 (in FIGS. 2A to 2D) may protrude in the vertical direction Z from the top surface of the tray 100. The protrusions 110 and 120 may surround the semiconductor package 200. The protrusions 110 and 120 are described in detail with reference to FIGS. 2A to 2D below.

The plurality of semiconductor packages 200 may be seated on the top surface of the tray 100. The semiconductor packages 200 may be spaced apart from each other at regular intervals (e.g., in the X and/or Y directions) to be parallel with each other on the tray 100. According to an embodiment, at least one semiconductor package 210 among the semiconductor packages 200 may obliquely sit on the tray 100 in a vertical direction. For example, the semiconductor package 210 may be seated on the tray 100 in a misaligned state. Here, the semiconductor package 210 seated on the tray 100 in a misaligned state may also be referred to as a misaligned semiconductor package, a semiconductor package, an oblique semiconductor package, and the like, and considered to mean the same unless stated otherwise. The semiconductor package 210 misaligned on the tray 100 is described in detail below with reference to FIGS. 2A to 2D.

A semiconductor package 200 may be seated on the top surface of the tray 100. The semiconductor package 200 may include at least one semiconductor chip. In an embodiment, the semiconductor chip may include a memory chip or a logic chip. For example, in an embodiment the memory chip may include a volatile memory chip, such as dynamic random access memory (DRAM) or static RAM (SRAM), or a non-volatile memory chip, such as phase-change RAM (PRAM), magnetoresistive RAM (MRAM), ferroelectric RAM (FeRAM), or resistive RAM (RRAM). For example, the logic chip may include a microprocessor such as a central processing unit (CPU), a graphics processing unit (GPU), or an application processor, an analog device, or a digital signal processor. However, embodiments of the present disclosure are not necessarily limited thereto. According to an embodiment, the semiconductor package 200 may correspond to a singulated semiconductor package obtained by a sawing process.

The inspector 500 may be configured to inspect the state of the semiconductor package 200 seated on the tray 100. According to an embodiment, the inspector 500 may be configured to inspect the degree of alignment of the semiconductor package 200 seated on the tray 100. For example, in an embodiment the inspector 500 may determine the coordinates of the center of the semiconductor package 200 seated on the tray 100. In an embodiment, the inspector may determine whether the semiconductor package 200 overlaps first and second protrusions 110, 120 (described below) in the Z direction. A controller 600 may then determine whether the semiconductor package 200 is correctly aligned on the tray 100 based on the center coordinates of the semiconductor package 200 that are detected by the inspector 500. For example, the controller 600 may determine whether the semiconductor package 200 is oblique (e.g., misaligned) on the tray 100 based on the detected center coordinates of the semiconductor package 200. Accordingly, the controller 600 may detect the misaligned semiconductor package 210 on the tray 100.

The inspector 500 may inspect the defective state of the semiconductor package 200 seated on the tray 100. For example, the inspector 500 may inspect whether there is a crack in the semiconductor package 200. In an embodiment, the inspector 500 may include a collimator, an autocollimator, or a distance sensor. However, embodiments of the present disclosure are not necessarily limited thereto.

The under vision camera 400 may be separated from the tray 100 in the first horizontal direction X. In an embodiment, the under vision camera 400 may measure the rotation angle, damage, center coordinates, or the like of the semiconductor package 200 through the bottom surface of the semiconductor package 200. The controller 600 may set a shift coordinate value of the picker 300 based on the center coordinates of the semiconductor package 200 and the rotation angle measured by the under vision camera 400. In an embodiment, the controller 600 may then transmit a feedback signal to the picker 300 based on the center coordinates of the semiconductor package 200 and the rotation angle measured by the under vision camera 400 so that the picker 300 may move to certain coordinates.

The picker 300 may be configured to move the semiconductor package 200 seated on the tray 100. According to an embodiment, the picker 300 may approach the semiconductor package 200 which is seated on the tray 100 in the vertical direction Z, directly contact the top surface of the semiconductor package 200, and separate the semiconductor package 200 from the tray 100 in the vertical direction Z by using adsorption. However, embodiments of the present disclosure are not necessarily limited thereto. In an embodiment, the picker 300 may move the semiconductor package 200 separated from the tray 100 to an area above the under vision camera 400. However, embodiments of the present disclosure are not necessarily limited thereto and the positional relationship between the semiconductor package 200 separated from the tray 100 and the under vision camera 400 may vary in some embodiments. According to an embodiment, the picker 300 may separate the misaligned semiconductor package 210 among the semiconductor packages 200, which are placed on the tray 100, from the tray 100 and then move the misaligned semiconductor package 210 to an area above the under vision camera 400 in the vertical direction Z. Accordingly, the bottom surface of the misaligned semiconductor package 210 may face the top surface of the under vision camera 400 in the vertical direction Z. According to an embodiment, the picker 300 may be configured to be rotatable around the Z axis.

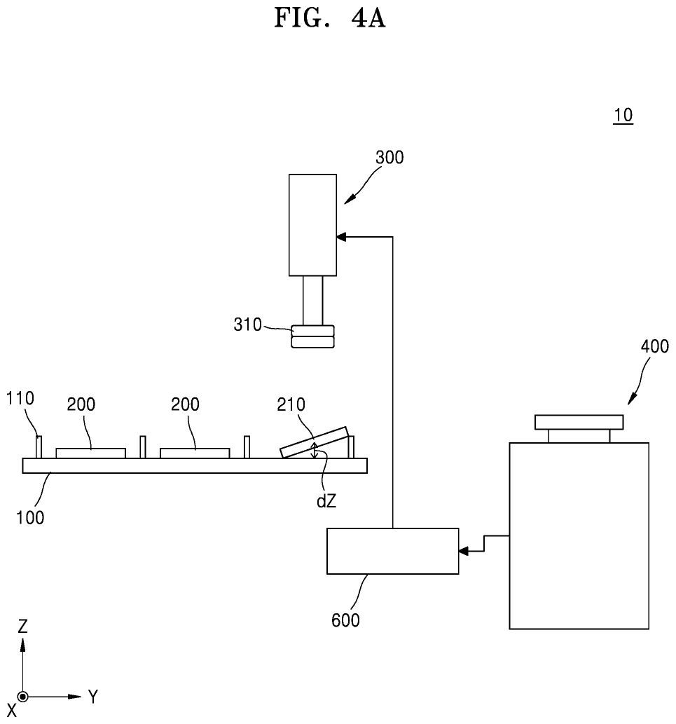

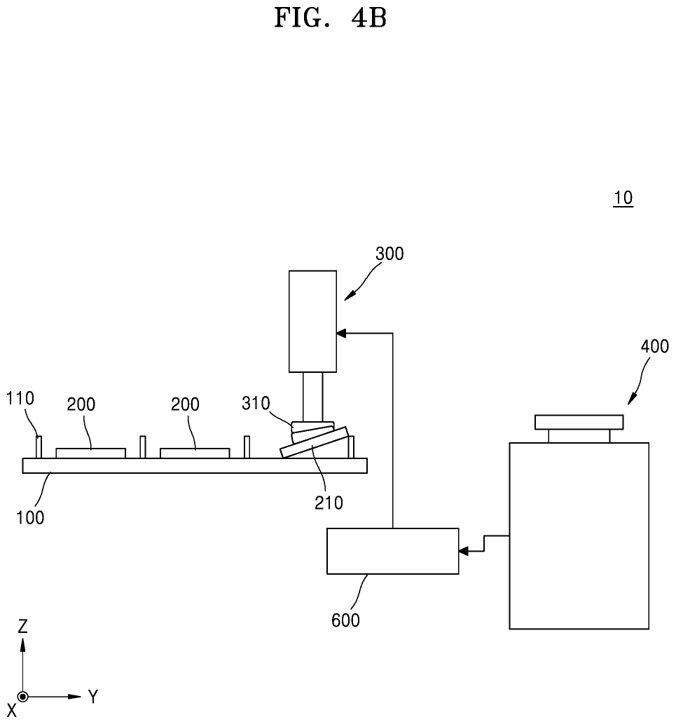

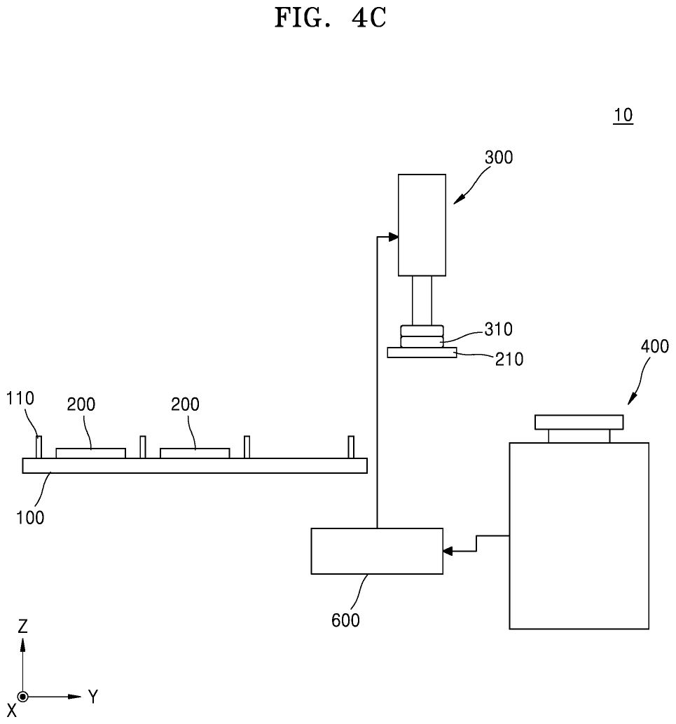

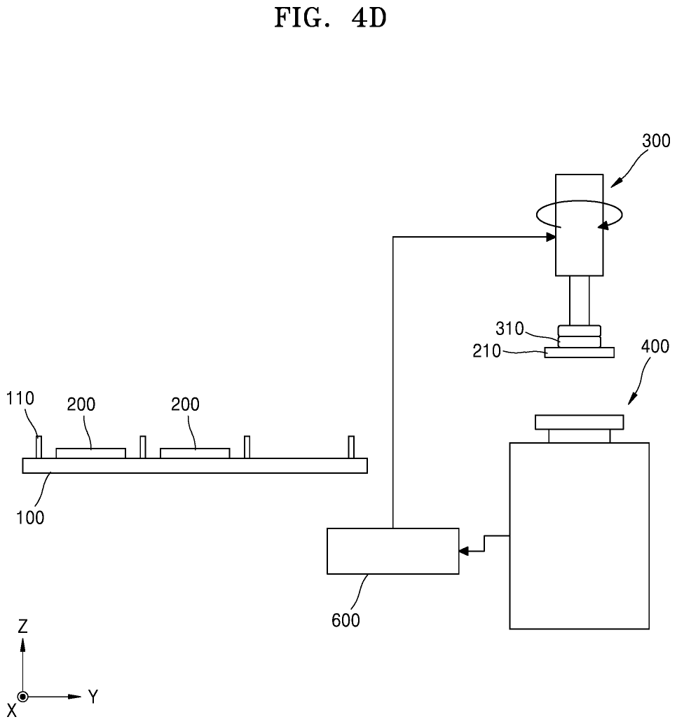

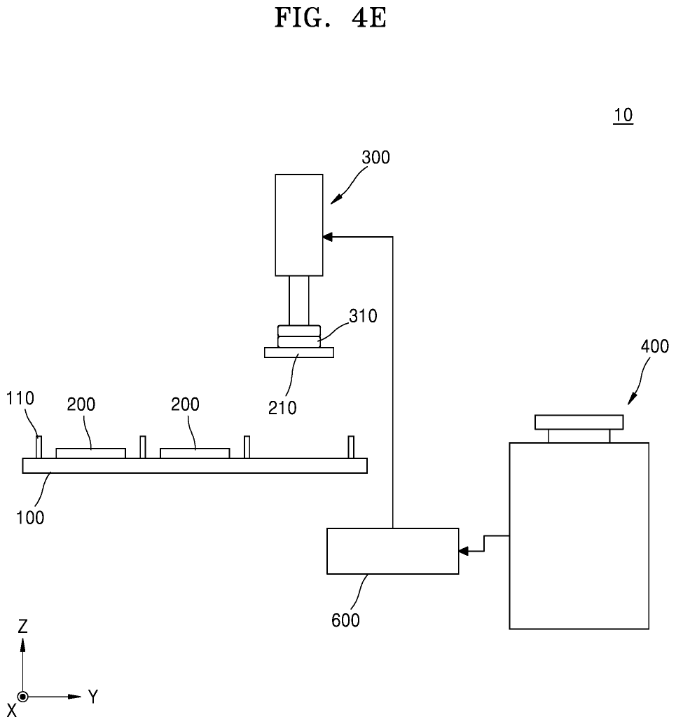

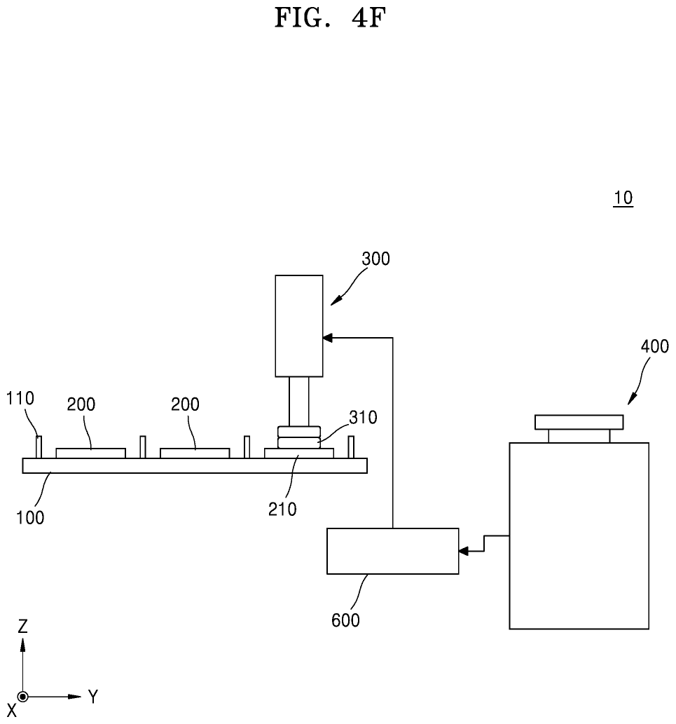

According to an embodiment, the picker 300 may include a buffer 310 (in FIGS. 4A to 4F). The buffer 310 may be the part of the picker 300 that directly contacts the top surface of a semiconductor package 200 and may reduce the impact applied to the semiconductor package 200 when the picker 300 directly contacts the semiconductor package 200. For example, in an embodiment the buffer 310 may include a bellows pad, a ball joint pad, or a gyro pad. However, embodiments of the present disclosure are not necessarily limited thereto. According to an embodiment, the buffer 310 may include an air cushion.

Based on the center coordinates of the semiconductor package 200, which is measured by the inspector 500, and the rotation angle of the semiconductor package 200, which is measured by the under vision camera 400, the controller 600 may be configured to correct a positional relationship between the semiconductor package 200 and the tray 100.

In an embodiment, the controller 600 may be implemented by hardware, firmware, software, or a combination thereof. For example, the controller 600 may include a computing device, such as a workstation computer, a desktop computer, a laptop computer, or a tablet computer. However, embodiments of the present disclosure are not necessarily limited thereto. The controller 600 may include a simple controller, a microprocessor, a complex processor such as a CPU or a GPU, a processor configured by software, or dedicated hardware or firmware. For example, the controller 600 may be implemented by a general-use computer or an application-specific hardware component, such as a digital signal processor (DSP), a field programmable gate array (FPGA), or an application specific integrated circuit (ASIC). However, embodiments of the present disclosure are not necessarily limited thereto. The controller 600 may be embodied as instructions which are stored in a machine-readable medium and may be read and executed by at least one processor. In an embodiment, the machine-readable medium may include a mechanism for storing and/or transmitting information in a form readable by a machine (e.g., a computing device). Examples of the machine-readable medium may include read-only memory (ROM), random access memory (RAM), magnetic disk storage media, optical storage media, flash memory devices, electrical, optical or acoustic, or other types of wave signals (e.g., carriers, infrared signals, digital signals, etc.), and other signals. However, embodiments of the present disclosure are not necessarily limited thereto.

In some embodiments, the controller 600 may set the movement of the tray 100 according to the degree of damage to each semiconductor package 200, which is measured by the inspector 500. For example, when at least one semiconductor package 200 is damaged to a certain level or beyond, such as when a crack, a break, or distortion occur in the semiconductor package 200, the controller 600 may stop transporting the tray 100.

According to an embodiment, the controller 600 may determine the degree of alignment of the semiconductor package 200 based on the center coordinate value of the semiconductor package 200 which is measured by the inspector 500, and then identify the misaligned semiconductor package 210. The controller 600 may control the picker 300 to move the misaligned semiconductor package 200 to an area above the under vision camera 400 so that the degree of distortion of the semiconductor package 200 is measured and then allow the semiconductor package 200 to be seated on the tray 100 in place (e.g., aligned in a target position) based on the degree of distortion of the semiconductor package 200.

FIGS. 2A to 2D are enlarged plan views of a region AA in FIG. 1. Redundant descriptions given above with reference to FIG. 1 are omitted below for economy of description.

Referring to FIGS. 2A to 2D, the tray 100 may include a first protrusion 110 and a second protrusion 120. In an embodiment, the first protrusion 110 and the second protrusion 120 may protrude from the top surface of the tray 100 in the vertical direction Z and surround an area that is larger than an area of the semiconductor package 210 along the X-Y plane.

According to an embodiment, a plurality of first protrusions 110 may extend in the first horizontal direction X on the tray 100 and may be spaced apart from each other at regular intervals in the second horizontal direction Y. A plurality of second protrusions 120 may extend in the second horizontal direction Y on the tray 100 and may be spaced apart from each other at regular intervals in the first horizontal direction X. According to an embodiment, two second protrusions 120 may be at opposite sides of the semiconductor package 210 in the first horizontal direction X.

Some of the semiconductor packages 200 (in FIG. 1) may sit on the tray 100 to be at respective target positions thereof (e.g., aligned semiconductor packages) and the other semiconductor packages 200 may be seated on the tray 100 to be out of position from respective target positions thereof (e.g., misaligned semiconductor packages). A target position of each semiconductor package 200 may refer to the inside of each of the first and second protrusions 110 and 120 on the tray 100. Accordingly, when the semiconductor package 210 is out of position from the target position thereof, the semiconductor package 210 may not be on the inside of each of the first and second protrusions 110 and 120 of the tray 100. At this time, the semiconductor package 210 out of position from the target position thereof, such as the misaligned semiconductor package 210, may overlap some of the first and second protrusions 110 and 120 of the tray 100 in the vertical direction Z.

The misaligned semiconductor package 210 may overlap in the vertical direction Z with a first protrusion 110, a second protrusion 120, or both the first protrusion 110 and the second protrusion 120. FIGS. 2A to 2D illustrate embodiments in which the semiconductor package 210 overlaps with both the first protrusion 110 and the second protrusion 120 in the vertical direction Z. However, misaligned states of the semiconductor package 210 are not necessarily limited thereto.

When the semiconductor package 210 is misaligned, the center coordinates of the semiconductor package 210 may be represented by C1, as shown in FIG. 2A. When a semiconductor package 200 (in FIG. 1) is correctly aligned, such as when the semiconductor package 200 is placed at a target position thereof, the center of the semiconductor package 200 may be represented by C0, as shown in FIG. 2B. C0 may also be understood as the center coordinates of the target position. As shown in FIG. 2C, C1, the center of the misaligned semiconductor package 210, may have a coordinate value difference from C0 in the first horizontal direction X represented by dX, and a coordinate value difference from C0 in the second horizontal direction Y represented by dY. At this time, the misaligned semiconductor package 210, of which the center coordinates are out of position from the target position by dX in the first horizontal direction X and is out of position from the target position by dY in the second horizontal direction Y, may be considered as having abnormal center coordinates.

The misaligned semiconductor package 210 may have a rotation angle d1 with respect to the X-Y plane, as shown in FIG. 2D. Consequently, the misaligned semiconductor package 210 may be seated on the tray 100 in a state in which the misaligned semiconductor package 210 is out of position from the target position by dX in the first horizontal direction X and by dY in the second horizontal direction Y and is rotated by d1 with respect to the X-Y plane.

There may be an empty space between the first protrusion 110 and the second protrusion 120. For example, the first protrusion 110 and the second protrusion 120 may be spaced apart from each other at regular intervals and thus have an empty space therebetween. There may also be an empty space between adjacent second protrusions 120 spaced apart from each other in the second horizontal direction Y. Since there is an empty space between the first protrusion 110 and the second protrusion 120 or between adjacent second protrusions 120, a portion of the semiconductor package 210 may be disposed in the empty space when the semiconductor package 210 is seated on the tray 100. Thus, a portion of the semiconductor package 210 may be trapped in the empty space. When a portion of the semiconductor package 210 is trapped in the empty space, the misaligned semiconductor package 210 may not move to the target position even when the tray 100 is vibrated to correct misalignment.

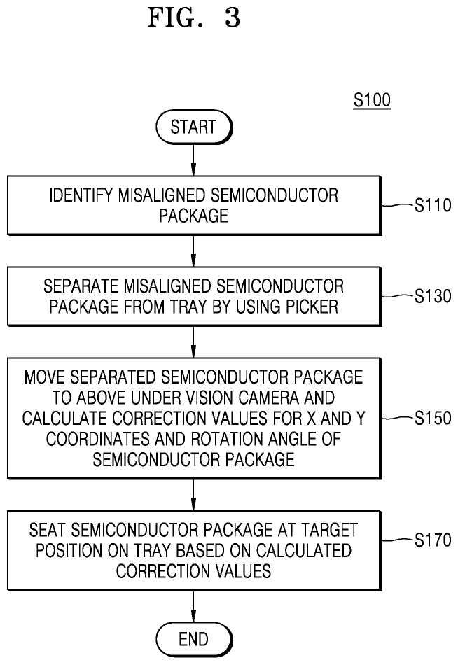

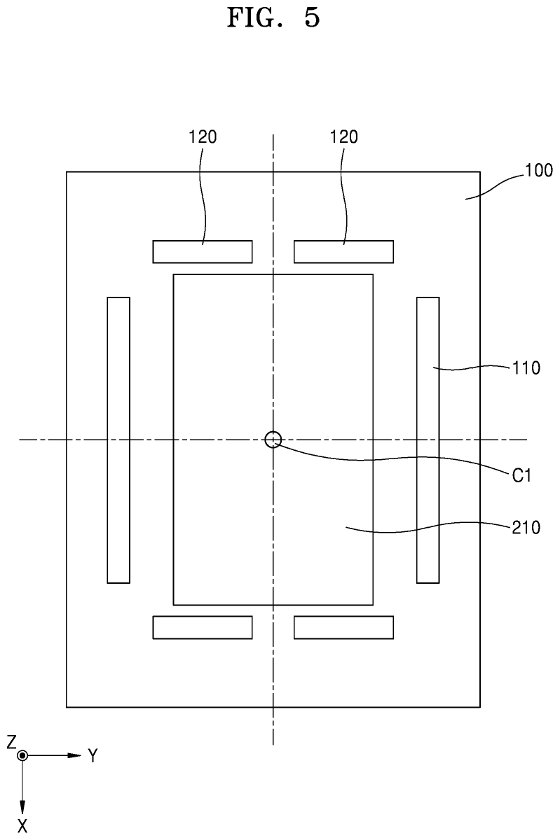

FIG. 3 is a schematic flowchart of a semiconductor package alignment method according to an embodiment. FIGS. 4A to 4F are schematic cross-sectional views of a semiconductor manufacturing apparatus according to embodiments. FIG. 5 is a schematic plan view of a semiconductor package aligned by a semiconductor package alignment method according to an embodiment.

A semiconductor package alignment method is described below with reference to FIGS. 1, 3, 4A to 4F, and 5 below. Redundant descriptions given above with reference to FIGS. 1 to 2D may be omitted below for economy of description.

Referring to FIG. 3, a semiconductor package alignment method S100 may include identifying a misaligned semiconductor package in operation S110, separating the misaligned semiconductor package from a tray by using a picker in operation S130, moving the separated semiconductor package to an area above an under vision camera and calculating correction values for the XY coordinates and rotation angle of the semiconductor package in operation S150, and placing the semiconductor package at a target position on the tray based on the calculated correction values in operation S170.

Referring to FIGS. 1 and 3, the misaligned semiconductor package 210 among the plurality of semiconductor packages 200 on the tray 100 may be identified in operation S110. For example, the tray 100 on which the plurality of semiconductor packages 200 are seated may be first provided. In an embodiment, the tray 100 may be moved to pass through an area where the inspector 500 is installed. However, embodiments of the present disclosure are not necessarily limited thereto and the inspector 500 may be moved to the tray 100 in some embodiments. While the tray 100 is passing through the area, the inspector 500 may inspect the alignment states of the semiconductor packages 200 on the tray 100. The controller 600 may identify a semiconductor package 200 located at a target position and a misaligned semiconductor package 210 based on the alignment states of the semiconductor packages 200, which are detected by the inspector 500. According to an embodiment, the controller 600 may identify the aligned semiconductor package 200 and the misaligned semiconductor package 210 based on the measured center coordinates of the semiconductor packages 200. For example, the controller 600 may determine whether each of the semiconductor packages 200 is correctly aligned, based on identifying differences between the center coordinates C0 (in FIG. 2B) of the target position and the center coordinates of each semiconductor package 200 to detect the misaligned semiconductor package 210.

According to an embodiment, the controller 600 may identify the aligned semiconductor package 200 and the misaligned semiconductor package 210 based on whether each of the semiconductor packages 200 overlaps with at least one of the first and second protrusions 110 and 120 (in FIG. 2A) in the vertical direction Z. For example, the controller 600 may identify a semiconductor package 200 that overlaps with the first protrusion 110 in the vertical direction Z as the misaligned semiconductor package 210 and may identify a semiconductor package 200 that does not overlap with the first protrusion 110 in the vertical direction Z as the aligned semiconductor package 200.

For example, the misaligned semiconductor package 210 may overlap with the first protrusion 110 in the vertical direction Z. The center of the misaligned semiconductor package 210 overlapping with the first protrusion 110 in the vertical direction Z may be separated from the top surface of the tray 100 by dZ in the vertical direction Z.

Referring to FIGS. 3, 4A, and 4B, the misaligned semiconductor package 210 may be separated from the tray 100 by using the picker 300 in operation S130. In an embodiment, the controller 600 may first move the picker 300 to above the misaligned semiconductor package 210 based on the center coordinates of the misaligned semiconductor package 210. The picker 300 may be moved to be above the center coordinates of the misaligned semiconductor package 210 in the vertical direction Z. For example, in an embodiment the picker 300 may be moved to face in the vertical direction Z the center of the misaligned semiconductor package 210 with respect to the X-Y plane. The picker 300 moved to above the misaligned semiconductor package 210 may be driven downwards in the vertical direction Z such that the buffer 310 of the picker 300 directly contacts the top surface of the misaligned semiconductor package 210, as shown in FIG. 4B. In an embodiment, the controller 600 may then move the picker 300 based on the distance dZ between the center of the misaligned semiconductor package 210 and the tray 100 in the vertical direction Z. Accordingly, the controller 600 may prevent the misaligned semiconductor package 210 from being damaged by a force generated when the misaligned semiconductor package 210 comes into direct contact with picker 300 and a normal force applied by the first protrusion 110. In an embodiment, the buffer 310 of the picker 300 may include a material that absorbs impact and may be coupled to the top surface of the misaligned semiconductor package 210 via vacuum adsorption. When the picker 300 moves upward in the vertical direction Z in a state in which the buffer 310 of the picker 300 is coupled to the misaligned semiconductor package 210, the misaligned semiconductor package 210 may be separated from the tray 100.

Referring to FIGS. 3, 4C, and 4D, in an embodiment the separated semiconductor package may be moved to an area (e.g., a region) above an under vision camera 400 and correction values for the XY coordinates and rotation angle of the semiconductor package may be calculated, in operation S150. The picker 300 may move the semiconductor package 210, which is separated from the tray 100, to above the under vision camera 400 (e.g., in the Z direction). In an embodiment, the semiconductor package 210 transported by the picker 300 may be positioned to be separated from the under vision camera 400 by a certain distance in the vertical direction Z. The semiconductor package 210 may be positioned to face the under vision camera 400 in the vertical direction Z while being spaced apart from the under vision camera 400 in the vertical direction Z.

When the semiconductor package 210 is located to face the under vision camera 400 in the vertical direction Z, the bottom surface of the semiconductor package 210 may face the top surface of the under vision camera 400. Based on information on the bottom surface of the semiconductor package 210, the under vision camera 400 may detect the rotation angle (d1 in FIG. 2D) of the semiconductor package 210 with respect to the X-Y plane, a degree (dX in FIG. 2C) to which the center coordinates of the semiconductor package 210 are out of position in the first horizontal direction X, and a degree (dY in FIG. 2C) to which the center coordinates of the semiconductor package 210 are out of position in the second horizontal direction Y. For example, the under vision camera 400 may measure the X-coordinate difference and the Y-coordinate difference between the center coordinates of the semiconductor package 210 and the center coordinates of the target position of the semiconductor package 210. The controller 600 may calculate the correction values for the X-coordinate, the Y-coordinate, and the rotation angle d1 of the semiconductor package 210 based on information detected by the under vision camera 400.

The controller 600 may rotate the picker 300 holding the semiconductor package 210 based on the calculated correction values so that the semiconductor package 210 may be aligned. For example, the picker 300 may be rotated above the under vision camera 400 around the Z axis by an angle (d1 in FIG. 2D) by which the semiconductor package 210 is out of position from the target position on the X-Y plane. Accordingly, the semiconductor package 210 may also be rotated by the angle by which the semiconductor package 210 is out of position from the target position.

Referring to FIGS. 3, 4E, and 4F, the semiconductor package 210 may be seated at the target position on the tray 100 based on the calculated correction values in operation S170. The controller 600 may move the picker 300 to the target position on the tray 100 based on the correction values calculated by using the under vision camera 400. The target position may allow the semiconductor package 210 to be placed on the tray 100 and positioned inside of the first and second protrusions 110 and 120 so that the misaligned semiconductor package 210 may be seated by the picker 300 on the tray 100 without overlapping the first protrusion 110 or the second protrusion 120 in the vertical direction Z. For example, the misaligned semiconductor package 210 may be seated in the inside of the first protrusion 110 and the second protrusion 120 on the tray 100 in operation S170.

Referring to FIG. 5, the previously misaligned semiconductor package 210 may be seated at the target position on the tray 100 by the semiconductor package alignment method S100. For example, the center coordinates C1 of the seated semiconductor package 210 may be substantially the same as or similar to the center coordinates of the target position. Even when the center coordinates C1 of the semiconductor package 210 are slightly different from the center coordinates of the target position, subsequent processes may be performed in instances in which the semiconductor package 210 is inside of the first protrusion 110 and the second protrusion 120.

According to the related art, in instances in which some of the plurality of semiconductor packages 200 seated on the tray are misaligned on the tray 100, the tray 100 is often vibrated to align misaligned semiconductor packages 210. There are also known methods in the related art in which the semiconductor packages 210 are manually aligning the misaligned semiconductor packages 210. However, when a misaligned semiconductor package 210 is not aligned through vibration or manual work, the manufacturing processes may stop. In comparative embodiments in which the misaligned semiconductor package 210 are aligned by vibration, the correctly aligned semiconductor packages 200 may also be shaken by the vibration and may collide with the first and second protrusions 110 and 120. Accordingly, the semiconductor packages 200 may be damaged. Additionally, there are frequent instances in which the vibration does not result in the semiconductor package 210 being successfully aligned.

However, according to an embodiment of the present disclosure, the semiconductor manufacturing apparatus 10 and the semiconductor package alignment method S100 may align the misaligned semiconductor package 210 without stopping equipment involved in the manufacturing process flow or damaging the other semiconductor packages 200 by moving the misaligned semiconductor package 210 to an area above the under vision camera 400 by using the picker 300, calculating correction values, and placing the semiconductor package 210 on a target position of the tray 100. The semiconductor manufacturing apparatus 10 may reduce the process time by automating the alignment of the misaligned semiconductor package 210.

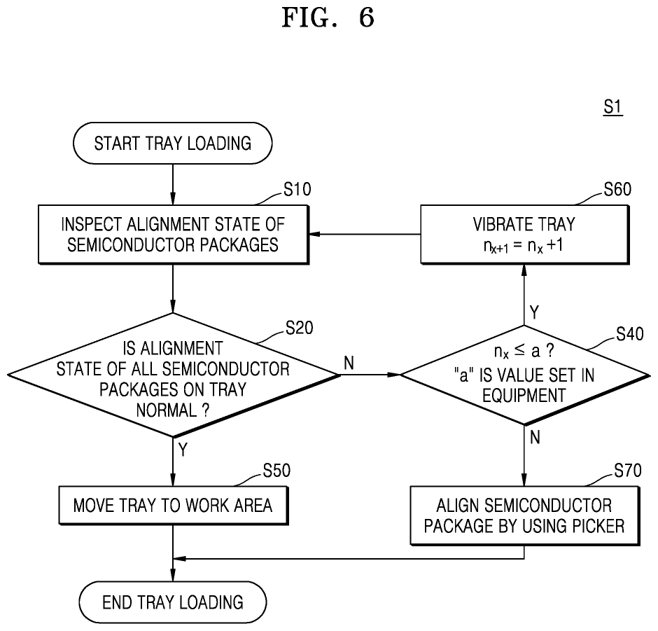

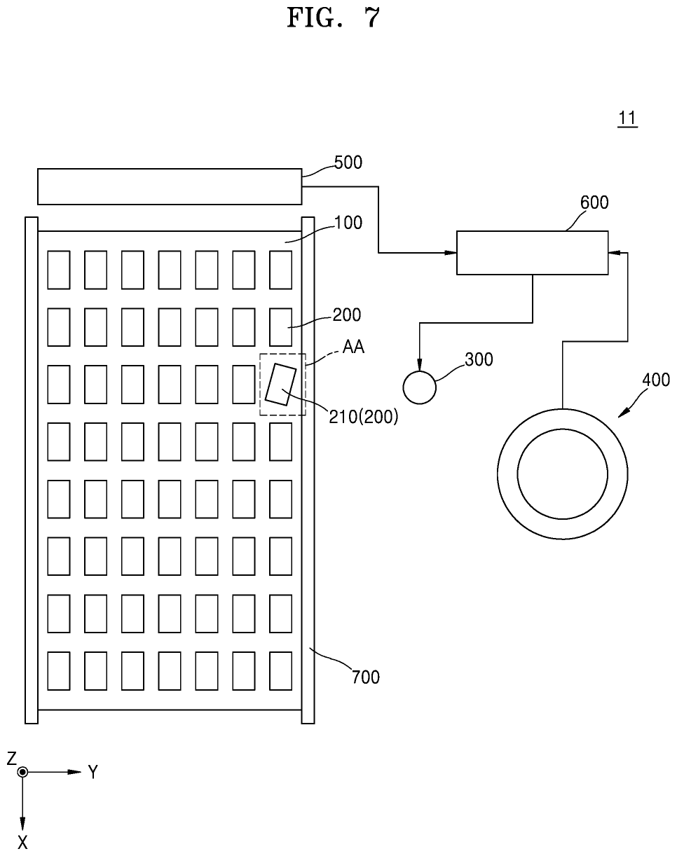

FIG. 6 is a schematic flowchart of a semiconductor package alignment method according to an embodiment. FIG. 7 is a schematic view schematically showing a semiconductor manufacturing apparatus according to an embodiment. A semiconductor package alignment method SI according to an embodiment is described below with reference to FIGS. 6 and 7. Redundant descriptions given above with reference to FIGS. 1 to 5 may be omitted below for economy of description.

Referring to FIGS. 6 and 7, the semiconductor package alignment method SI may include inspecting the alignment state of semiconductor packages in operation S10. Operation S10 is substantially the same as or similar to operation S110 of identifying a misaligned semiconductor package, which has been described above with reference to FIGS. 1 and 3, and thus the description thereof is omitted for economy of description.

Subsequently, whether the alignment state of all semiconductor packages 200 on the tray 100 is normal may be determined in operation S20.

In instances in which the alignment state of all semiconductor packages 200 on the tray 100 is normal (e.g., all semiconductor packages 200 are identified as being aligned in the respective target positions), the tray 100 may be moved to a work area in operation S50 for further manufacturing processes. In an instance in which there is at least one misaligned semiconductor package 210, operation S40 may be performed. In operation S40, a value nₓ is determined. In an embodiment, when the value nₓ is less than or equal to a certain integer value “a”, the tray 100 may be vibrated in operation S60. When the value nₓ is greater than the certain integer value “a”, the semiconductor package 210 may be aligned by using the picker 300 in operation S70.

The value nₓ may refer to the number of times the tray 100 is vibrated and the certain integer value “a” may be set (e.g., predetermined) in the equipment in some embodiments. For example, in an embodiment in which the value “a” is set as 5, when the alignment state of the semiconductor packages 200 is inspected in operation S10 and operations S20 and S40 are performed due to the presence of the misaligned semiconductor package 210, the value nₓ is 0 that is less than the value “a” of 5, because vibration of the tray 100 in operation S60 has not yet been performed. However, embodiments of the present disclosure are not necessarily limited to the value of “a” being 5, and the value of “a” may be variously modified. Accordingly, the vibration of the tray 100 may be performed in operation S60. The vibration of the tray 100 may be considered as an operation of shaking the tray 100 horizontally, vertically, or horizontally and vertically by using vibration generated by a vibrator 700 shown in FIG. 7. Due to the vibration, the misaligned semiconductor package 210 may no longer overlap the first and second protrusions 110 and 120 (in FIG. 2A) in the vertical direction Z.

After operation S60, operation S10 may be performed again to inspect the alignment state of the semiconductor packages 200. In instances in which there is still a misaligned semiconductor package 210 determined in operation S20 which is performed after operation S10, operation S40 may be newly performed. At this time, since the vibration of the tray 100 has been performed once, the value nₓ may be 1. Since the value nₓ is still less than the set value “a” of 5, operation S60 may be newly performed. When the vibration of the tray 100 is performed six times while the processes S10, S20, S40 and S60 described above are repeated, operation S70 may then be performed after operation S40 because the value nₓ is 6 in operation S40 which is greater than “a”.

Operation S70 may include separating the misaligned semiconductor package 210 from the tray 100 by using the picker 300 in operation S130, moving the separated semiconductor package 210 to an area above the under vision camera 400 and calculating correction values for the XY coordinates and rotation angle of the semiconductor package 210 in operation S150, and placing the semiconductor package 210 at the target position on the tray 100 based on the correction values in operation S170. Operations S130, S150, and S170 are substantially the same as or similar to those described above with reference to FIGS. 3 and 4A to 4F, and thus descriptions thereof are omitted for economy of description.

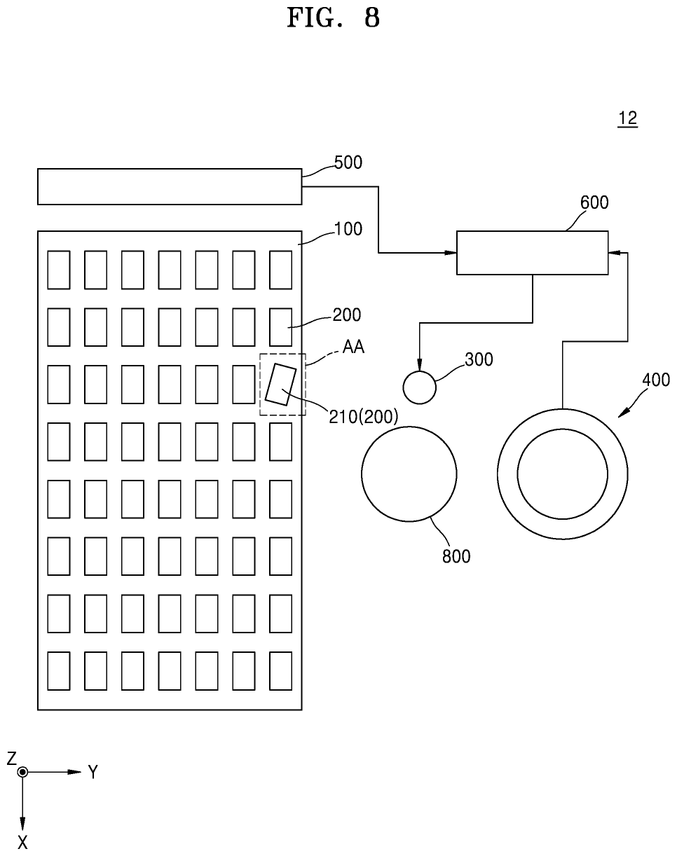

FIG. 8 is a schematic view schematically showing a semiconductor manufacturing apparatus according to an embodiment. Redundant descriptions of the semiconductor manufacturing apparatus 10 of FIG. 1 may be omitted for economy of description, and a semiconductor manufacturing apparatus 12 of FIG. 8 is described below, focusing on the differences from the semiconductor manufacturing apparatus 10 of FIG. 1.

Referring to FIG. 8, the semiconductor manufacturing apparatus 12 may include a tray 100, a semiconductor package 200, an inspector 500, an under vision camera 400, a station 800, a picker 300, and a controller 600.

The station 800 may be separated in a horizontal direction (e.g., the X direction) from both the tray 100 and the under vision camera 400. The station 800 may be configured to allow the semiconductor package 200 to be seated thereon. The station 800 may be configured to be rotatable around the Z axis. According to an embodiment, a misaligned semiconductor package 210 may be moved by the picker 300 from the tray 100 to above the under vision camera 400 and then seated on the top surface of the station 800.

The semiconductor package 200 may be fixed to the top surface of the station 800. At this time, the semiconductor package 200 may rotate in the XY plane along with the rotation of the station 800. For example, the station 800 may rotate in a state in which the semiconductor package 200 is fixed to the top surface of the station 800, and thus, the semiconductor package 200 may rotate at the same angle as the station 800. According to an embodiment, the station 800 may include an actuator. The actuator may provide power for rotating the station 800.

The controller 600 may rotate the station 800 based on correction values measured by using the under vision camera 400. The misaligned semiconductor package 210 that has been rotated by the rotation of the station 800 may be placed back on the tray 100 by the picker 300. At this time, the misaligned semiconductor package 210 may not overlap the first and second protrusions 110 and 120 (in FIG. 2A) of the tray 100 in the vertical direction Z. For example, the misaligned semiconductor package 210 may be seated at a target position on the tray 100.

Consequently, the misaligned semiconductor package 210 may be rotated by the rotation of the station 800 besides the rotation of the picker 300 and thus be seated on the tray 100 without being out of position, such as overlapping the first and second protrusions 110 and 120 (in FIG. 2A) in the vertical direction Z.

The rotation of the misaligned semiconductor package 210 is not necessarily limited to the rotation by the picker 300 or the station 800 and may be performed by any device that may rotate the misaligned semiconductor package 210 based on a correction value calculated based on a value detected by the under vision camera 400 and the inspector 500.

While the present disclosure has been particularly shown and described with reference to non-limiting embodiments thereof, it will be understood that various changes in form and details may be made therein without departing from the spirit and scope of the present disclosure.

What is claimed is:

1. A semiconductor manufacturing apparatus comprising:
a semiconductor package;
a tray having the semiconductor package seated thereon;
an inspector inspecting an alignment state of the semiconductor package;
a protrusion on a top surface of the tray and extending in a Z direction that is a vertical direction, the protrusion surrounding a side surface of the semiconductor package when the semiconductor package is in an aligned state wherein the semiconductor package overlaps at least a portion of the protrusion in the Z direction when the semiconductor package is in a misaligned state;
an under vision camera detecting a rotation angle of the semiconductor package with respect to an X-Y plane defined in a first horizontal direction X and a second horizontal direction Y that cross the Z direction; and
a picker moving the semiconductor package between the tray and an area above the under vision camera.

2. The semiconductor manufacturing apparatus of claim 1, wherein the picker includes a buffer directly contacting a top surface of the semiconductor package.

3. The semiconductor manufacturing apparatus of claim 2, wherein the buffer includes a pad selected from a bellows pad, a ball joint pad and a gyro pad.

4. The semiconductor manufacturing apparatus of claim 1, wherein the picker is rotatable around a Z axis extending in the Z direction.

5. The semiconductor manufacturing apparatus of claim 1, wherein the inspector determines center coordinates of the semiconductor package.

6. The semiconductor manufacturing apparatus of claim 1, wherein the inspector determines whether the semiconductor package overlaps the protrusion in the vertical direction.

7. The semiconductor manufacturing apparatus of claim 1, further comprising:
a station spaced apart from the tray, the picker further moving the semiconductor package to the station to have the semiconductor package seated thereon,
wherein the station is rotatable around a Z axis extending in the Z direction.

8. The semiconductor manufacturing apparatus of claim 1, further comprising a vibrator vibrating the tray.

9. The semiconductor manufacturing apparatus of claim 1, wherein the under vision camera measures an X-coordinate difference defined in the first horizontal direction X and a Y-coordinate difference defined in the second horizontal direction Y between center coordinates of the semiconductor package and center coordinates of a target position of the semiconductor package.

10. The semiconductor manufacturing apparatus of claim 1, further comprising a controller controlling movement of the semiconductor package that is in the misaligned state by the picker to correct a positional relationship between the semiconductor package and the tray based on a value detected by each of the inspector and the under vision camera.

11. The semiconductor manufacturing apparatus of claim 10, wherein the controller corrects the positional relationship between the semiconductor package and the tray based on center coordinates of the semiconductor package defined in the first horizontal direction X and the second horizontal direction Y and the rotation angle of the semiconductor package with respect to the X-Y plane.

12. A semiconductor manufacturing apparatus comprising:
a semiconductor package;
a tray having the semiconductor package seated thereon;
a vibrator vibrating the tray;
an inspector inspecting an alignment state of the semiconductor package;
a protrusion on a top surface of the tray and extending in a Z direction that is a vertical direction, the protrusion surrounding a side surface of the semiconductor package when the semiconductor package is in an aligned state, wherein the semiconductor package overlaps at least a portion of the protrusion in the Z direction when the semiconductor package is in a misaligned state;
an under vision camera detecting a rotation angle of the semiconductor package with respect to an X-Y plane defined in a first horizontal direction X and a second horizontal direction Y that cross the Z direction;
a picker moving the semiconductor package between the tray and an area above the under vision camera;
a controller controlling movement of the semiconductor package that is in the misaligned state by the picker to correct a positional relationship between the semiconductor package and the tray based on a value detected by each of the inspector and the under vision camera; and
the picker includes a buffer directly contacting a top surface of the semiconductor package.

13. The semiconductor manufacturing apparatus of claim 12, wherein the inspector determines whether the semiconductor package overlaps the protrusion in the Z direction.

14. The semiconductor manufacturing apparatus of claim 12, wherein the under vision camera measure an X-coordinate difference defined in the first horizontal direction X and a Y-coordinate difference defined in the second horizontal direction Y between center coordinates of the semiconductor package and center coordinates of a target position of the semiconductor package.

15. The semiconductor manufacturing apparatus of claim 12, wherein the protrusion includes a first protrusion and a second protrusion, the first protrusion and the second protrusion are separated from each other in a horizontal direction.

16. The semiconductor manufacturing apparatus of claim 12, wherein the controller corrects the positional relationship between the semiconductor package and the tray based on center coordinates of the semiconductor package defined in the first horizontal direction X and the second horizontal direction Y and the rotation angle of the semiconductor package with respect to the X-Y plane.

17. The semiconductor manufacturing apparatus of claim 12, wherein the buffer adsorbs a top surface of the semiconductor package via vacuum adsorption and includes one pad selected from a bellows pad, a ball joint pad, and a gyro pad.

18. A semiconductor package alignment method comprising:
providing a tray having a plurality of semiconductor packages seated thereon;
inspecting an alignment state of the plurality of semiconductor packages;
identifying a misaligned semiconductor package that is seated on the tray in a misaligned state based on the inspection;
separating the misaligned semiconductor package from the tray by using a picker;
moving the separated semiconductor package to an area above an under vision camera;
calculating correction values respectively for XY coordinates defined in a first horizontal direction X and a second horizontal direction Y and a rotation angle of the separated semiconductor package with respect to an X-Y plane defined in the first horizontal direction X and the second horizontal direction Y through the under vision camera; and
seating the separated semiconductor package at a target position on the tray based on the calculated correction values,
wherein the tray includes a protrusion surrounding each of the plurality of semiconductor packages thereon,
the misaligned semiconductor package overlaps the protrusion in a Z direction that is a vertical direction crossing the first horizontal direction X and second horizontal direction Y, and the target position is a position where the semiconductor package does not overlap the protrusion in the Z direction.

19. The semiconductor package alignment method of claim 18, further comprising vibrating the tray after identifying the misaligned semiconductor packages.

20. The semiconductor package alignment method of claim 18, wherein the picker includes a buffer directly contacting a top surface of the semiconductor package, the buffer includes a bellows pad, and the picker is rotatable around a Z axis extending in the Z direction.
